(19) United States
(12) Patent Application Publication
(10) Pub. No.: US 2015/0041052 A1
(43) Pub. Date: Feb. 12, 2015

(54) WAVELENGTH CONVERSION LAYER ON A GLASS PLATE TO ENHANCE SOLAR HARVESTING EFFICIENCY

(71) Applicant: NITTO DENKO CORPORATION, Osaka (JP)

(72) Inventors: Hongxi Zhang, Temecula, CA (US); Michiharu Yamamoto, Carlsbad, CA (US)

(21) Appl. No.: 14/376,104

(22) PCT Filed: Jan. 31, 2013
(86) PCT No.: PCT/US2013/024225

§ 371 Date: Jul. 31, 2014

Related U.S. Application Data
(60) Provisional application No. 61/593,683, filed on Feb. 1, 2012.

(51) Int. Cl. H01L 31/055; H01L 51/00; H01L 51/44; H01L 31/0296; H01L 31/0312; H01L 31/032; H01L 31/18; H01L 31/0272

(52) U.S. Cl. CPC H01L 31/055; H01L 31/18; H01L 51/0001; H01L 31/0272; H01L 31/0296; H01L 31/0312; H01L 31/0322; H01L 51/44
USPC 156/244.11; 136/257; 427/165; 156/60

(57) ABSTRACT

Described herein are wavelength converting devices comprising a glass plate and a wavelength conversion layer over a glass plate that can be applied to solar cells, solar panels, or photovoltaic devices to enhance solar harvesting efficiency of those devices. The wavelength conversion layer of the wavelength converting device comprises a polymer matrix and one, or multiple, luminescent dyes that convert photons of a particular wavelength to a more desirable wavelength.

### CROSS-REFERENCE TO RELATED APPLICATIONS

This patent application claims the benefit of priority to U.S. Provisional Patent Application No. 61/593,683, filed Feb. 1, 2012. The foregoing application is fully incorporated by reference for all purposes.

### BACKGROUND OF THE INVENTION

1. Field of the Invention

The present invention generally relates to a wavelength converting device comprising a wavelength conversion layer on a substrate layer. Embodiments of this invention are useful generally as conversion layers for solar cells, solar panels, or photovoltaic devices, as well as other devices and applications requiring wavelength conversion.

2. Description of the Related Art

The utilization of solar energy offers a promising alternative energy source to the traditional fossil fuels. Thus, the development of devices that convert solar energy into electricity, such as photovoltaic devices (also known as solar cells), has drawn significant attention in recent years. Several different types of mature photovoltaic devices have been developed. Examples include: a Silicon based device, a III-V and II-VI PN junction device, a Copper-Indium-Gallium-Selenium (CIGS) thin film device, an organic sensitizer device, an organic thin film device, and a Cadmium Sulfide/Cadmium Telluride (CdS/CdTe) thin film device, as well as others. More detail on these devices can be found in the literature, such as Lin et al., “High Photoelectric Conversion Efficiency of Metal Phthalocyanine/Fullerene Heterojunction Photovoltaic Device” (International Journal of Molecular Sciences 2011). However, the photoelectric conversion efficiency of many current photovoltaic devices could be improved to result in improved energy production.

One technique for improving the efficiency of photovoltaic devices is to apply a wavelength down-shifting film to the device. A deficiency of several photovoltaic devices is that they are unable to effectively utilize the entire spectrum of light. The windows through which light is absorbed in these photovoltaic devices absorb certain wavelengths of light (typically the shorter UV wavelengths) instead of allowing the light to pass through to the photoconductive material layer where it is converted into electricity. Thus, some radiative energy is lost to the device itself. Application of a wavelength down-shifting films that absorbs shorter wavelength photons and re-emit them at more favorable longer wavelengths, which can then be absorbed by the photoconductive layer in the device, allows higher conversion into electricity.

This phenomenon is often observed in the thin film CdS/CdTe and CIGS solar cells which both use CdS as the window layer. The low cost and high efficiency of these thin film solar cells has drawn significant attention in recent years, with typical commercial cells having photoelectric conversion efficiencies of 10-16%. One issue with these devices is the energy gap of CdS, approximately 2.41 eV, which causes light at wavelengths below 514 nm to be absorbed by CdS instead of passing through to the photoconductive layer where it can be converted into energy. The inability to utilize the entire spectrum of light effectively reduces the overall photoelectric conversion efficiency of the device.

There have been numerous reports disclosing the utilization of a wavelength down-shifting material to improve the performance of photovoltaic devices. For example, U.S. Patent Application Publication No. 2009/0151785 discloses a silicon based solar cell which contains a wavelength down-shifting inorganic phosphor material. U.S. Patent Application Publication No. US 2011/0011455 discloses an integrated solar cell comprising a plasmonic layer, a wavelength conversion layer, and a photovoltaic layer. U.S. Pat. No. 7,791,157 discloses a solar cell with a wavelength conversion layer containing a quantum dot compound. U.S. Patent Application Publication No. 2010/0294339 discloses an integrated photovoltaic device containing a luminescent down-shifting material, however no example embodiments were constructed. U.S. Patent Application Publication No. 2010/0012183 discloses a thin film solar cell with a wavelength down-shifting photo-luminescent medium; however, no examples are provided. U.S. Patent Application Publication No. 2008/0236667 discloses an enhanced spectrum conversion film made in the form of a thin film polymer comprising an inorganic fluorescent powder. However, each of these disclosures uses time-consuming and sometimes complicated and expensive techniques which may require special tool sets to apply the wavelength conversion film to the solar cell device. These techniques include spin-coating, drop-casting, sedimentation, solvent evaporation, chemical vapor deposition, physical vapor deposition, etc.

### SUMMARY OF THE INVENTION

Materials configured for high efficiency conversion of wavelengths are provided. In some embodiments, the materials are useful for converting a portion of solar radiation to useable wavelengths for solar energy conversion devices. Several embodiments provide a device comprising a wavelength conversion layer on a glass plate. Such devices can be configured to be applied to solar cells, solar panels, and photovoltaic devices to enhance solar harvesting efficiency when applied to the light incident surface of those devices. In several embodiments, the device comprises a wavelength conversion layer on a glass plate, wherein the wavelength conversion layer comprises a transparent polymer matrix and at least one chromophore. In several embodiments the chromophore receives as input at least one photon having a first wavelength, and provides as output at least one photon having a second wavelength which is different than the first.

The wavelength converting device comprising a wavelength conversion layer and a glass plate, as described herein, may include additional layers. For example, the wavelength converting device may comprise an adhesive layer in between the glass plate and wavelength conversion layer. In several embodiments, the wavelength converting device may also comprise an additional protective layer on top of the wavelength conversion layer, designed to protect and prevent oxygen and moisture penetration into the wavelength conversion layer. The converting device may further comprise a polymer layer comprising a UV absorber, designed to prevent harmful high energy photons from contacting the wavelength conversion layer. Additionally, the structure may comprise one or more removable liners attached to the wavelength conversion layer, the glass plate, or both. In several embodiments, the removable liners are designed to protect the structure from photodegradation until it is installed onto a solar cell, solar panel, or photovoltaic device.

Another aspect of the invention relates to a method of forming the structure described herein by a) formulating a solution comprising a polymer material and at least one chromophore dissolved in a solvent, b) spin coating the solution directly onto the glass plate to obtain a wavelength conversion layer and c) removing the solvent from the wavelength conversion layer by drying the structure in an oven.

Another aspect of the invention is a method of forming the structure by a) formulating a powder mixture of a polymer material and at least one chromophore, b) using an extruder to heat the mixture and form the wavelength conversion layer and c) using a laminator to directly apply the wavelength conversion layer to the glass plate.

Another aspect of the invention relates to a method for improving the performance of photovoltaic devices, solar cells, solar modules, or solar panels, comprising applying the structure, as described herein, to the light incident side of the device. The solar harvesting efficiency of various devices, such as a silicon based device, a III-V or II-VI junction device, a Copper-Indium-Gallium-Selenium (CIGS) thin film device, an organic sensitizer device, an organic thin film device, or a Cadmium Sulfide/Cadmium Telluride (CdS/CdTe) thin film device, can be improved.

The structure comprising a wavelength conversion layer and a glass plate may be provided in various lengths and widths so as to accommodate smaller individual solar cells, or entire solar panels. In several embodiments, the structure may be adhered to the light incident surface of a solar cell, solar panel, or photovoltaic device using a transparent adhesive.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

These and other embodiments are described in greater detail below.

### BRIEF DESCRIPTION OF THE DRAWINGS

FIG. 1 illustrates an embodiment of the wavelength converting device comprising a wavelength conversion layer on a glass plate.

FIG. 2 illustrates an embodiment of the wavelength converting device comprising a wavelength conversion layer on a glass plate, with an adhesive layer in between the wavelength conversion layer and the glass plate.

FIG. 3 illustrates an embodiment of the wavelength converting device comprising a wavelength conversion layer on a glass plate, with a protective layer on top of the wavelength conversion layer. The protective layer is configured to prevent oxygen and moisture penetration into the wavelength conversion layer.

FIG. 4 illustrates an embodiment of the wavelength converting device comprising a wavelength conversion layer on a glass plate, with a protective layer on top of the wavelength conversion layer. The protective layer comprises a UV absorber which prevents harmful high energy photons from contacting the wavelength conversion layer.

FIG. 5 illustrates an embodiment of the wavelength converting device comprising a wavelength conversion layer on a glass plate, with a removable liner on top of the wavelength conversion layer. In several embodiments, the removable liner prevents solar irradiation into the wavelength converting device.

FIG. 6 illustrates an embodiment of the wavelength converting device comprising a wavelength conversion layer on a glass plate, with a removable liner on top of the wavelength conversion layer and a removable liner underneath the glass plate. In several embodiments, the removable liners prevent solar irradiation into the wavelength converting device.

FIG. 7 illustrates an embodiment of the wavelength converting device comprising a wavelength conversion layer on a glass plate, applied to a solar panel. In several embodiments, the wavelength converting device enhances solar harvesting efficiency of the solar panel.

FIG. 8 illustrates an embodiment of the wavelength converting device comprising a wavelength conversion layer on a glass plate, applied to a solar panel. In several embodiments, the wavelength converting device enhances solar harvesting efficiency of the solar panel.

### DETAILED DESCRIPTION OF THE PREFERRED EMBODIMENT

Wavelength converting devices comprising a wavelength conversion layer on a glass plate are provided. When the wavelength converting device is applied to the light incident surface of a solar cell, solar panel, or photovoltaic device, the photoelectric conversion efficiency is enhanced. The inventors have discovered a wavelength converting device comprising a wavelength conversion layer on a substrate plate that can be constructed and applied to the light incident surface of a solar cell. In several embodiments, application of the present wavelength converting device comprising a wavelength conversion layer on a glass plate enhances the solar harvesting efficiency of a solar cell device. Some embodiments of the wavelength converting device comprise a wavelength conversion layer on a glass plate that can be configured to be compatible with different types and sizes of solar cells and solar panels, including: Silicon based devices, III-V and II-VI PN junction devices, CIGS thin film devices, organic sensitizer devices, organic thin film devices, CdS/CdTe thin film devices, dye sensitized devices, etc. Embodiments of the invention comprise a wavelength conversion layer on a substrate plate that can be configured to be compatible with amorphous Silicon solar cells, microcrystalline Silicon solar cells, and crystalline Silicon solar cells. Additionally, the wavelength converting device is applicable to future devices or those currently existing, devices that are already in service. In some embodiments, the wavelength converting device can be cut or manufactured to a custom size as needed to fit the device.

In several embodiments of the wavelength converting device, the wavelength conversion layer comprises a polymer matrix. In several embodiments, the polymer matrix of the wavelength conversion layer is formed from a substance selected from the group consisting of polyethylene terephthalate, polymethyl methacrylate, polyvinyl butyral, ethylene vinyl acetate, ethylene tetrafluoroethylene, polyimide, amorphous polycarbonate, polystyrene, siloxane sol-gel, polyurethane, polyacrylate, and combinations thereof.

In several embodiments of the wavelength converting device, the polymer matrix may be made of one host polymer, a host polymer and a co-polymer, or multiple polymers.

Preferably, the polymer matrix material used in the wavelength conversion layer has a refractive index in the range of about 1.4 to about 1.7. In several embodiments, the refractive index of the polymer matrix material used in the wavelength conversion layer is in the range of about 1.45 to about 1.55.

The above mentioned chromophores are especially suitable for use in the solar cells applications because they are surprisingly more stable in harsh environmental conditions than currently available wavelength converting chromophores. This stability makes these chromophores advantageous in their use as wavelength conversion materials for solar cells. Without such photostability, these chromophores would degrade and lose efficiency.

Preferably, the at least one chromophore is present in the polymer matrix of the wavelength conversion layer in an amount in the range of about 0.01 wt % to about 10 wt %, by weight of the polymer matrix. In several embodiments, the at least one chromophore is present in the polymer matrix of the wavelength conversion layer in an amount in the range of about 0.01 wt % to about 3 wt %, by weight of the polymer matrix. In several embodiments, the at least one chromophore is present in the polymer matrix of the wavelength conversion layer in an amount in the range of about 0.05 wt % to about 2 wt %, by weight of the polymer matrix. In several embodiments, the at least one chromophore is present in the polymer matrix of the wavelength conversion layer in an amount in the range of about 0.1 wt % to about 1 wt %, by weight of the polymer matrix.

A chromophore compound, sometimes referred to as a luminescent dye or fluorescent dye, is a compound that absorbs photons of a particular wavelength or wavelength range, and re-emits the photon at a different wavelength or wavelength range. Chromophores used in film media can greatly enhance the performance of solar cells and photovoltaic devices. However, such devices are often exposed to extreme environmental conditions for long periods of time, e.g., 20 plus years. As such, maintaining the stability of the chromophore over a long period of time is important. In several embodiments, chromophore compounds with good photostability for long periods of time, e.g., 20,000 plus hours of illumination under one sun (AM1.5G) irradiation with <10% degradation, are preferably used in the structure comprising a wavelength conversion layer on a glass plate described herein.

In several embodiments, the chromophore is configured to convert incoming photons of a first wavelength to a different second wavelength. Various chromophores can be used. In several embodiments, the at least one chromophore is an organic dye. In several embodiments, the at least one chromophore is selected from perylene derivative dyes, benzotriazole derivative dyes, benzothiadiazole derivative dyes, and combinations thereof.

In some embodiments, the chromophores represented by general formulae I-a, I-b, II-a, II-b, III-a, III-b, IV and V are useful as fluorescent dyes in various applications, including in wavelength conversion films. As shown in the formulae, the dye comprises a benzo heterocyclic system in some embodiments. In some embodiments, perylene derivative dye may be used. Additional detail and examples, without limiting the scope of the invention, on the types of compounds that can be used are described below.

As used herein, an “electron donor group” is defined as any group which increases the electron density of the 2H-benzo[d][1,2,3]triazole system.

An “electron donor linker” is defined as any group that can link two 2H-benzo[d][1,2,3]triazole systems providing conjugation of their π orbitals, which can also increase or have neutral effect on the electron density of the 2H-benzo[d][1,2,3]triazole to which they are connected.

An “electron acceptor group” is defined as any group which decreases the electron density of the 2H-benzo[d][1,2,3]triazole system. The placement of an electron acceptor group at the N-2 position of the 2H-benzo[d][1,2,3]triazole ring system.

The term “alkyl” refers to a branched or straight fully saturated acyclic aliphatic hydrocarbon group (i.e. composed of carbon and hydrogen containing no double or triple bonds). Alkyls include, but are not limited to, methyl, ethyl, propyl, isopropyl, butyl, isobutyl, tertiary butyl, pentyl, hexyl, and the like.

The term “heteroalkyl” used herein refers to an alkyl group comprising one or more heteroatoms. When two or more heteroatoms are present, they may be the same or different.

The term “cycloalkyl” used herein refers to saturated aliphatic ring system radical having three to twenty carbon atoms including, but not limited to, cyclopropyl, cyclopentyl, cyclohexyl, cycloheptyl, and the like.

The term “alkenyl” used herein refers to a monovalent straight or branched chain radical of from two to twenty carbon atoms containing a carbon double bond including, but not limited to, 1-propenyl, 2-propenyl, 2-methyl-1-propenyl, 1-butenyl, 2-butenyl, and the like.

The term “alkynyl” used herein refers to a monovalent straight or branched chain radical of from two to twenty carbon atoms containing a carbon triple bond including, but not limited to, 1-propynyl, 1-butynyl, 2-butynyl, and the like.

The term “aryl” used herein refers to homocyclic aromatic radical whether one ring or multiple fused rings. Examples of aryl groups include, but are not limited to, phenyl, naphthyl, phenanthrenyl, naphthacenyl, fluorenyl, pyrenyl, and the like. Further examples include:

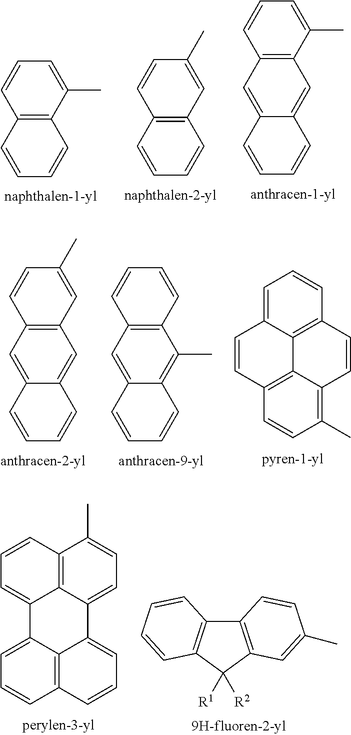

The term “heteroaryl” used herein refers to an aromatic group comprising one or more heteroatoms, whether one ring or multiple fused rings. When two or more heteroatoms are present, they may be the same or different. In fused ring systems, the one or more heteroatoms may be present in only one of the rings. Examples of heteroaryl groups include, but are not limited to, benzothiazyl, benzoxazyl, quinazolinyl, quinolinyl, isoquinolinyl, quinoxalinyl, pyridinyl, pyrrolyl, oxazolyl, indolyl, thiazyl and the like.

The term “alkaryl” or “alkylaryl” used herein refers to an alkyl-substituted aryl radical. Examples of alkaryl include, but are not limited to, ethylphenyl, 9,9-dihexyl-9H-fluorene, and the like.

The term “aralkyl” or “arylalkyl” used herein refers to an aryl-substituted alkyl radical. Examples of aralkyl include, but are not limited to, phenylpropyl, phenylethyl, and the like.

The term “heteroaryl” used herein refers to an aromatic ring system radical in which one or more ring atoms are heteroatoms, whether one ring or multiple fused rings. When two or more heteroatoms are present, they may be the same or different. In fused ring systems, the one or more heteroatoms may be present in only one of the rings. Examples of heteroaryl groups include, but are not limited to, benzothiazyl, benzoxazyl, quinazolinyl, quinolinyl, isoquinolinyl, quinoxalinyl, pyridinyl, pyridazinyl, pyrimidinyl, pyrazinyl, pyrrolyl, oxazolyl, indolyl, and the like. Further examples of substituted and unsubstituted heteroaryl rings include:

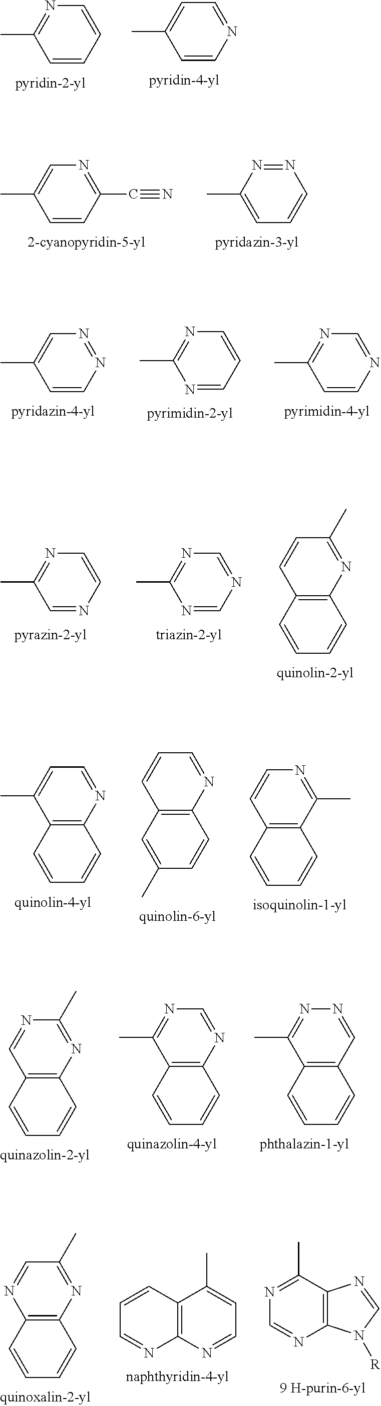

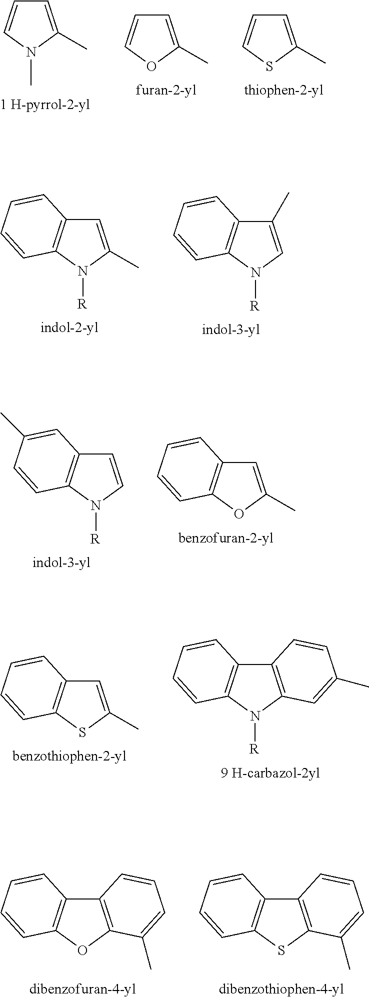

The term “alkoxy” used herein refers to straight or branched chain alkyl radical covalently bonded to the parent molecule through an —O— linkage. Examples of alkoxy groups include, but are not limited to, methoxy, ethoxy, propoxy, isopropoxy, butoxy, n-butoxy, sec-butoxy, t-butoxy and the like.

The term “heteroatom” used herein refers to S (sulfur), N (nitrogen), and O (oxygen).

The term “cyclic amino” used herein refers to either secondary or tertiary amines in a cyclic moiety. Examples of cyclic amino groups include, but are not limited to, aziridinyl, piperidinyl, N-methylpiperidinyl, and the like.

The term “cyclic imido” used herein refers to an imide in the radical of which the two carbonyl carbons are connected by a carbon chain. Examples of cyclic imide groups include, but are not limited to, 1,8-naphthalimide, pyrrolidine-2,5-dione, 1H-pyrrole-2,5-dione, and the likes.

The term “aryloxy” used herein refers to an aryl radical covalently bonded to the parent molecule through an —O— linkage.

The term “acyloxy” used herein refers to a radical R—C(═O)O—.

The term “carbamoyl” used herein refers to —NHC(═O)R.

The term “keto” and “carbonyl” used herein refers to C═O.

The term “carboxy” used herein refers to —COOR.

The term “ester” used herein refers to —C(═O)O—.

The term “amido” used herein refers to —NRC(═O)R′.

The term “amino” used herein refers to —NR′R″

As used herein, a substituted group is derived from the unsubstituted parent structure in which there has been an exchange of one or more hydrogen atoms for another atom or group. When substituted, the substituent group(s) is (are) one or more group(s) individually and independently selected from C₁-C₆ alkyl, C₁-C₆ alkenyl, C₁-C₆ alkynyl, C₃-C₇ cycloalkyl (optionally substituted with halo, alkyl, alkoxy, carboxyl, haloalkyl, CN, —CF₃, and —OCF₃), cycloalkyl geminally attached, C₁-C₆ heteroalkyl, C₃-C₁₀ heterocycloalkyl (e.g., tetrahydrofuryl) (optionally substituted with halo, alkyl, alkoxy, carboxyl, CN, —SO₂-alkyl, —CF₃, and —OCF₃), aryl (optionally substituted with halo, alkyl, aryl optionally substituted with C₁-C₆ alkyl, arylalkyl, alkoxy, aryloxy, carboxyl, amino, imido, amido (carbamoyl), optionally substituted cyclic imido, cyclic amido, CN, —NH—C(═O)-alkyl, —CF₃, and —OCF₃), arylalkyl (optionally substituted with halo, alkyl, alkoxy, aryl, carboxyl, CN, —CF₃, and —OCF₃), heteroaryl (optionally substituted with halo, alkyl, alkoxy, aryl, heteroaryl, aralkyl, carboxyl, CN, —SO₂-alkyl, —CF₃, and —OCF₃), halo (e.g., chloro, bromo, iodo and fluoro), cyano, hydroxy, optionally substituted cyclic imido, amino, imido, amido, —CF₃, C₁-C₆ alkoxy, aryloxy, acyloxy, sulfhydryl (mercapto), halo(C₁-C₆)alkyl, C₁-C₆ alkylthio, arylthio, mono- and di-(C₁-C₆)alkyl amino, quaternary ammonium salts, amino(C₁-C₆)alkoxy, hydroxy(C₁-C₆)alkylamino, amino(C₁-C₆)alkylthio, cyanoamino, nitro, carbamoyl, keto (oxy), carbonyl, carboxy, glycolyl, glycyl, hydrazino, guanyl, sulfamyl, sulfonyl, sulfinyl, thiocarbonyl, thiocarboxy, sulfonamide, ester, C-amide, N-amide, N-carbamate, O-carbamate, urea and combinations thereof. Wherever a substituent is described as “optionally substituted” that substituent can be substituted with the above substituents.

### Formulae I-a and I-b

Some embodiments provide a chromophore having one of the structures below:

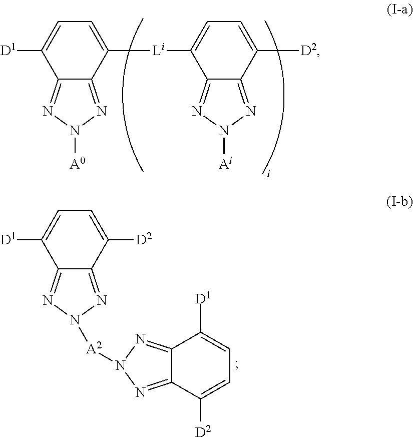

wherein D¹ and D² are electron donating groups, Lⁱ is an electron donor linker, and A⁰ and Aⁱ are electron acceptor groups. In some embodiments, where more than one electron donor group is present, the other electron donor groups may be occupied by another electron donor, a hydrogen atom, or another neutral substituent. In some embodiments, at least one of the D¹, D², and Lⁱ is a group which increases the electron density of the 2H-benzo[d][1,2,3]triazole system to which it is attached.

In formulae I-a and I-b, i is an integer in the range of 0 to 100. In some embodiments, i is an integer in the range of 0 to 50, 0 to 30, 0 to 10, 0 to 5, or 0 to 3. In some embodiments, i is 0, 1, 2, 3, 4, 5, 6, 7, 8, 9, or 10.

In formulae I-a and I-b, A⁰ and Aⁱ are each independently selected from the group consisting of optionally substituted alkyl, optionally substituted alkenyl, optionally substituted heteroalkyl, optionally substituted aryl, optionally substituted heteroaryl, optionally substituted amino, optionally substituted amido, optionally substituted cyclic amido, optionally substituted cyclic imido, optionally substituted alkoxy, and optionally substituted carboxy, and optionally substituted carbonyl.

In some embodiments, A⁰ and Aⁱ are each independently selected from the group consisting of optionally substituted heteroaryl, optionally substituted aryl, optionally substituted cyclic imido, optionally substituted C₁₋₈ alkyl, and optionally substituted C₁₋₈ alkenyl; wherein the substituent for optionally substituted heteroaryl is selected from the group consisting of alkyl, aryl and halogen; the substitutent for optionally substituted aryl is —NR¹—C(═O)R² or optionally substituted cyclic imido, wherein R¹ and R² are as described above.

In some embodiments, A⁰ and Aⁱ are each independently phenyl substituted with a moiety selected from the group consisting of —NR¹—C(═O)R² and optionally substituted cyclic imido, wherein R¹ and R² are as described above.

In some embodiments, A⁰ and Aⁱ are each optionally substituted heteroaryl or optionally substituted cyclic imido; wherein the substituent for optionally substituted heteroaryl and optionally substituted cyclic imido is selected from the group consisting of alkyl, aryl and halogen. In some embodiments, at least one of the A⁰ and Aⁱ is selected from the group consisting of: optionally substituted pyridinyl, optionally substituted pyridazinyl, optionally substituted pyrimidinyl, optionally substituted pyrazinyl, optionally substituted triazinyl, optionally substituted quinolinyl, optionally substituted isoquinolinyl, optionally substituted quinazolinyl, optionally substituted phthalazinyl, optionally substituted quinoxalinyl, optionally substituted naphthyridinyl, and optionally substituted purinyl.

In other embodiments, A⁰ and Aⁱ are each optionally substituted alkyl. In other embodiments, A⁰ and Aⁱ are each optionally substituted alkenyl. In some embodiments, at least one of the A⁰ and Aⁱ is selected from the group consisting of:

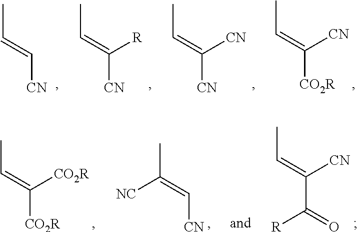

wherein R is optionally substituted alkyl.

In formula I-a and I-b, A² is selected from the group consisting of optionally substituted alkylene, optionally substituted alkenylene, optionally substituted arylene, optionally substituted heteroarylene, ketone, ester, and

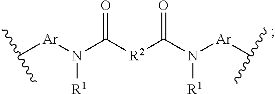

wherein Ar is optionally substituted aryl or optionally substituted heteroaryl. R¹ is selected from the group consisting of H, alkyl, alkenyl, aryl, heteroaryl, aralkyl, alkaryl; and R² is selected from the group consisting of optionally substituted alkylene, optionally substituted alkenylene, optionally substituted arylene, optionally substituted heteroarylene, ketone, and ester; or R¹ and R² may be connected together to form a ring.

In some embodiments, A² is selected from the group consisting of optionally substituted arylene, optionally substituted heteroarylene, and

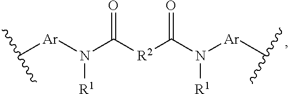

wherein Ar, R¹ and R² are as described above.

In formulae I-a and I-b, D¹ and D² are each independently selected from the group consisting of hydrogen, optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido, provided that D¹ and D² are not both hydrogen.

In some embodiments, D¹ and D² are each independently selected from the group consisting of hydrogen, optionally substituted aryl, optionally substituted heteroaryl, and amino, provided that D¹ and D² are not both hydrogen. In some embodiments, D¹ and D² are each independently selected from the group consisting of hydrogen, optionally substituted aryl, optionally substituted heteroaryl, and diphenylamino, provided that D¹ and D² are not both hydrogen.

In some embodiments, D¹ and D² are each independently optionally substituted aryl. In some embodiments, D¹ and D² are each independently phenyl optionally substituted by alkoxy or amino. In other embodiments, D¹ and D² are each independently selected from hydrogen, optionally substituted benzofuranyl, optionally substituted thiophenyl, optionally substituted furanyl, dihydrothienodioxinyl, optionally substituted benzothiophenyl, and optionally substituted dibenzothiophenyl, provided that D¹ and D² are not both hydrogen.

In some embodiments, the substituent for optionally substituted aryl and optionally substituted heteroaryl may be selected from the group consisting of alkoxy, aryloxy, aryl, heteroaryl, and amino.

In formulae I-a and I-b, Lⁱ is independently selected from the group consisting of optionally substituted alkylene, optionally substituted alkenylene, optionally substituted alkynylene, optionally substituted arylene, optionally substituted heteroarylene. In some embodiments, Lⁱ is selected from the group consisting of optionally substituted heteroarylene and optionally substituted arylene.

In some embodiments, at least one of the Lⁱ is selected from the group consisting of: 1,2-ethylene, acetylene, 1,4-phenylene, 1,1′-biphenyl-4,4′-diyl, naphthalene-2,6-diyl, naphthalene-1,4-diyl, 9H-fluorene-2,7-diyl, perylene-3,9-diyl, perylene-3,10-diyl, or pyrene-1,6-diyl, 1H-pyrrole-2,5-diyl, furan-2,5-diyl, thiophen-2,5-diyl, thieno[3,2-b]thiophene-2,5-diyl, benzo[c]thiophene-1,3-diyl, dibenzo[b,d]thiophene-2,8-diyl, 9H-carbozole-3,6-diyl, 9H-carbozole-2,7-diyl, dibenzo[b,d]furan-2,8-diyl, 10H-phenothiazine-3,7-diyl, and 10H-phenothiazine-2,8-diyl; wherein each moiety is optionally substituted.

### Formulae II-a and II-b

Some embodiments provide a chromophore having one of the structures below:

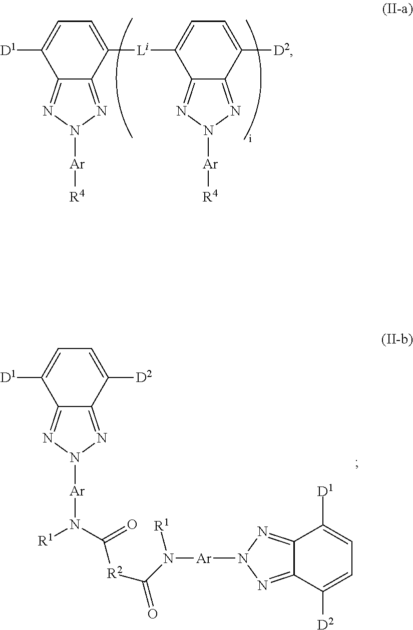

wherein i is an integer in the range of 0 to 100. In some embodiments, i is an integer in the range of 0 to 50, 0 to 30, 0 to 10, 0 to 5, or 0 to 3. In some embodiments, i is 0, 1, 2, 3, 4, 5, 6, 7, 8, 9, or 10.

In formulae II-a and II-b, Ar is optionally substituted aryl or optionally substituted heteroaryl. In some embodiments, aryl substituted with an amido or a cyclic imido group at the N-2 position of the 2H-benzo[d][1,2,3]triazole ring system provides unexpected and improved benefits.

In formulae II-a and II-b, R⁴ is

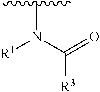

or optionally substituted cyclic imido; R¹ is each independently selected from the group consisting of H, alkyl, alkenyl, aryl, heteroaryl, aralkyl, alkaryl; R³ is each independently selected from the group consisting of optionally substituted alkyl, optionally substituted alkenyl, optionally substituted aryl, optionally substituted heteroaryl; or R¹ and R³ may be connected together to form a ring.

In some embodiments, R⁴ is optionally substituted cyclic imido selected from the group consisting of:

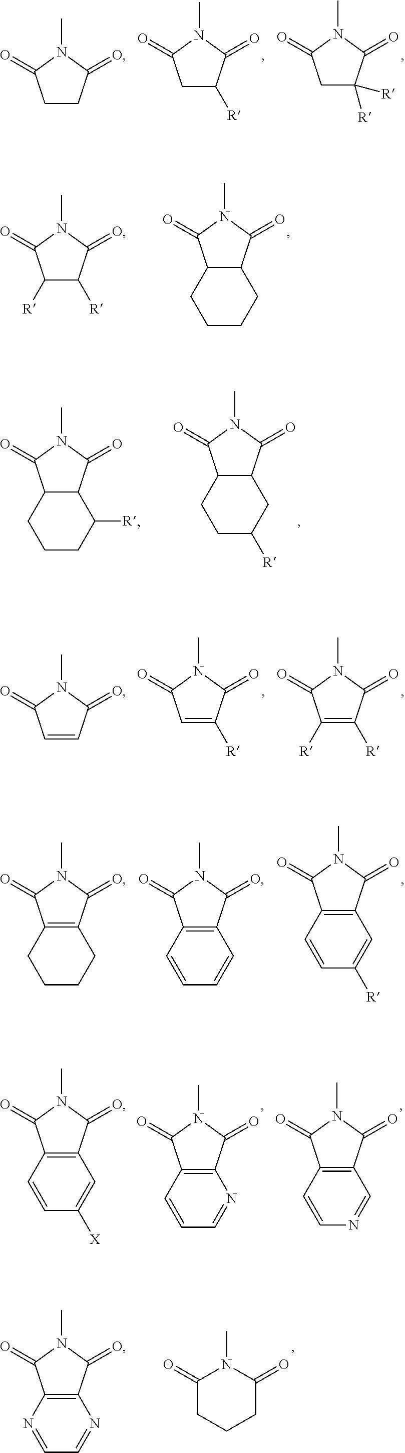

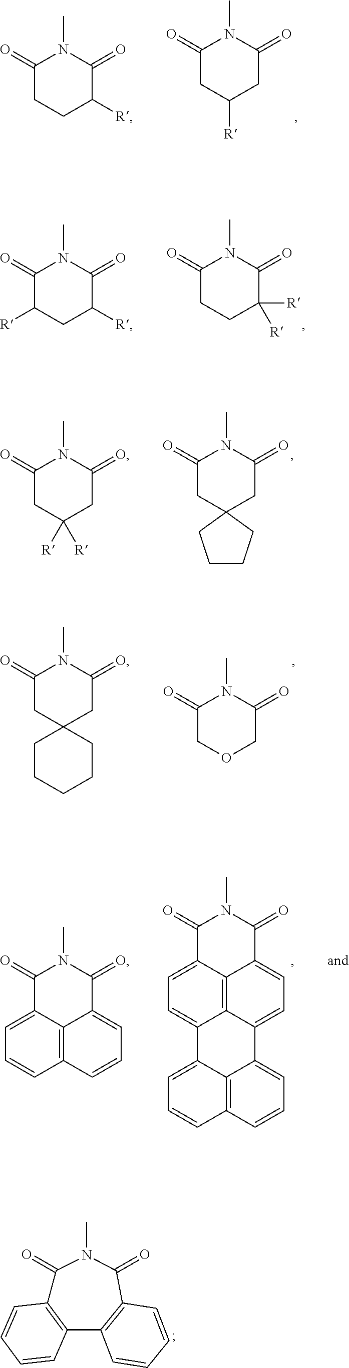

and wherein R′ is each optionally substituted alkyl or optionally substituted aryl; and X is optionally substituted heteroalkyl.

In formulae II-a and II-b, R² is selected from the group consisting of optionally substituted alkylene, optionally substituted alkenylene, optionally substituted arylene, optionally substituted heteroarylene.

In formulae II-a and II-b, D¹ and D² are each independently selected from the group consisting of hydrogen, optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido, provided that D¹ and D² are not both hydrogen.

In formulae II-a and II-b, Lⁱ is independently selected from the group consisting of optionally substituted alkylene, optionally substituted alkenylene, optionally substituted alkynylene, optionally substituted arylene, optionally substituted heteroarylene.

In some embodiments, at least one of the Lⁱ is selected from the group consisting of: 1,2-ethylene, acetylene, 1,4-phenylene, 1,1′-biphenyl-4,4′-diyl, naphthalene-2,6-diyl, naphthalene-1,4-diyl, 9H-fluorene-2,7-diyl, perylene-3,9-diyl, perylene-3,10-diyl, or pyrene-1,6-diyl, 1H-pyrrole-2,5-diyl, furan-2,5-diyl, thiophen-2,5-diyl, thieno[3,2-b]thiophene-2,5-diyl, benzo[c]thiophene-1,3-diyl, dibenzo[b,d]thiophene-2,8-diyl, 9H-carbozole-3,6-diyl, 9H-carbozole-2,7-diyl, dibenzo[b,d]furan-2,8-diyl, 10H-phenothiazine-3,7-diyl, and 10H-phenothiazine-2,8-diyl; wherein each moiety is optionally substituted.

### Formulae III-a and III-b

Some embodiments provide a chromophore having one of the structures below:

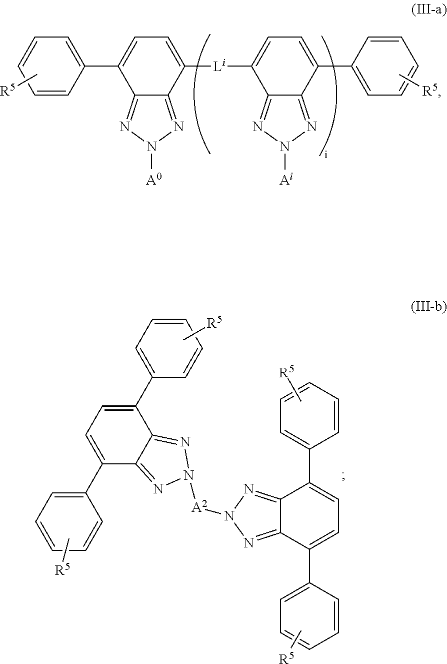

The placement of an alkyl group in formulae (III-a) and (III-b) at the N-2 position of the 2H-benzo[d][1,2,3]triazole ring system along with substituted phenyls at the C-4 and C-7 positions provides unexpected and improved benefits. In formula III-a and III-b, i is an integer in the range of 0 to 100. In some embodiments, i is an integer in the range of 0 to 50, 0 to 30, 0 to 10, 0 to 5, or 0 to 3. In some embodiments, i is 0, 1, 2, 3, 4, 5, 6, 7, 8, 9, or 10.

In formula III-a and III-b, A⁰ and Aⁱ are each independently selected from the group consisting of optionally substituted alkyl, optionally substituted alkenyl, optionally substituted heteroalkyl, optionally substituted amido, optionally substituted alkoxy, optionally substituted cabonyl, and optionally substituted carboxy.

In some embodiments, A⁰ and Aⁱ are each independently unsubstituted alkyl or alkyl substituted by a moiety selected from the group consisting of: —NRR″, —OR, —COOR, —COR, —CONHR, —CONRR″, halo and —CN; wherein R is C₁-C₂₀ alkyl, and R″ is hydrogen or C₁-C₂₀ alkyl. In some embodiments, the optionally substituted alkyl may be optionally substituted C₁-C₄₀ alkyl. In some embodiments, A⁰ and the Aⁱ are each independently C₁-C₄₀ alkyl or C₁-C₂₀ haloalkyl.

In some embodiments, A⁰ and Aⁱ are each independently C₁-C₂₀ haloalkyl, C₁-C₄₀ arylalkyl, or C₁-C₂₀ alkenyl.

In formulae III-a and III-b, each R⁵ is independently selected from the group consisting of optionally substituted alkoxy, optionally substituted aryloxy, optionally substituted acyloxy, and amino. In some embodiments, R⁵ may attach to phenyl ring at ortho and/or para position. In some embodiments, R⁵ may be alkoxy represented by the formula OCₙH₂ₙ₊₁ where n=1-40. In some embodiments, R⁵ may be aryloxy represented by the following formulae: ArO or O—CR—OAr where R is alkyl, substituted alkyl, aryl, or heteroaryl, and Ar is any substituted or unsubstituted aryl, or substituted or unsubstituted heteroaryl. In some embodiments, R⁵ may be acyloxy represented by the formula OCOCₙH₂ₙ₊₁ where n=1-40.

In formulae III-a and III-b, A² is selected from the group consisting of optionally substituted alkylene, optionally substituted alkenylene, optionally substituted arylene, optionally substituted heteroarylene, ketone, ester, and

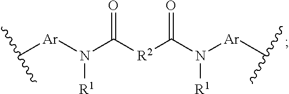

wherein Ar is optionally substituted aryl or optionally substituted heteroaryl, R¹ is selected from the group consisting of H, alkyl, alkenyl, aryl, heteroaryl, aralkyl, alkaryl; and R² is selected from the group consisting of optionally substituted alkylene, optionally substituted alkenylene, optionally substituted arylene, optionally substituted heteroarylene, ketone, and ester; or R¹ and R² may be connected together to form a ring.

In formulae III-a and III-b, Lⁱ is independently selected from the group consisting of optionally substituted alkylene, optionally substituted alkenylene, optionally substituted alkynylene, optionally substituted arylene, optionally substituted heteroarylene.

In some embodiments, at least one of the Lⁱ is selected from the group consisting of: 1,2-ethylene, acetylene, 1,4-phenylene, 1,1′-biphenyl-4,4′-diyl, naphthalene-2,6-diyl, naphthalene-1,4-diyl, 9H-fluorene-2,7-diyl, perylene-3,9-diyl, perylene-3,10-diyl, or pyrene-1,6-diyl, 1H-pyrrole-2,5-diyl, furan-2,5-diyl, thiophen-2,5-diyl, thieno[3,2-b]thiophene-2,5-diyl, benzo[c]thiophene-1,3-diyl, dibenzo[b,d]thiophene-2,8-diyl, 9H-carbozole-3,6-diyl, 9H-carbozole-2,7-diyl, dibenzo[b,d]furan-2,8-diyl, 10H-phenothiazine-3,7-diyl, and 10H-phenothiazine-2,8-diyl; wherein each moiety is optionally substituted.

### Formula IV

Some embodiments provide a chromophore having the structure below:

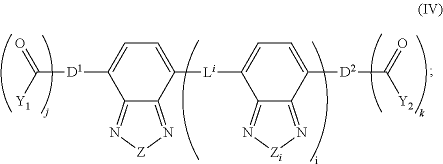

wherein i is an integer in the range of 0 to 100. In some embodiments, i is an integer in the range of 0 to 50, 0 to 30, 0 to 10, 0 to 5, or 0 to 3. In some embodiments, i is 0, 1, 2, 3, 4, 5, 6, 7, 8, 9, or 10.

In formula IV, Z and Zᵢ are each independently selected from the group consisting of —O—, —S—, —Se—, —Te—, —NR⁶—, —CR⁶═CR⁶—, and —CR⁶═N—, wherein R⁶ is hydrogen, optionally substitute C₁-C₆ alkyl, or optionally substituted C₁-C₁₀ aryl; and

In formula IV, D¹ and D² are independently selected from the group consisting of optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido; j is 0, 1 or 2, and k is 0, 1, or 2. In some embodiments, the —C(═O)Yᵢ and —C(═O)Y₂ groups may attach to the substituent(s) of the optionally substituted moiety for D¹ and D².

In formula IV, Y₁ and Y₂ are independently selected from the group consisting of optionally substituted aryl, optionally substituted alkyl, optionally substituted cycloalkyl, optionally substituted alkoxy, and optionally substituted amino; and

In formula IV, Lⁱ is independently selected from the group consisting of optionally substituted alkylene, optionally substituted alkenylene, optionally substituted alkynylene, optionally substituted arylene, optionally substituted heteroarylene.

In some embodiments, at least one of the Lⁱ is selected from the group consisting of: 1,2-ethylene, acetylene, 1,4-phenylene, 1,1′-biphenyl-4,4′-diyl, naphthalene-2,6-diyl, naphthalene-1,4-diyl, 9H-fluorene-2,7-diyl, perylene-3,9-diyl, perylene-3,10-diyl, or pyrene-1,6-diyl, 1H-pyrrole-2,5-diyl, furan-2,5-diyl, thiophen-2,5-diyl, thieno[3,2-b]thiophene-2,5-diyl, benzo[c]thiophene-1,3-diyl, dibenzo[b,d]thiophene-2,8-diyl, 9H-carbozole-3,6-diyl, 9H-carbozole-2,7-diyl, dibenzo[b,d]furan-2,8-diyl, 10H-phenothiazine-3,7-diyl, and 10H-phenothiazine-2,8-diyl; wherein each moiety is optionally substituted.

With regard to Lⁱ in any of the formulae above, the electron linker represents a conjugated electron system, which may be neutral or serve as an electron donor itself. In some embodiments, some examples are provided below, which may or may not contain additional attached substituents.

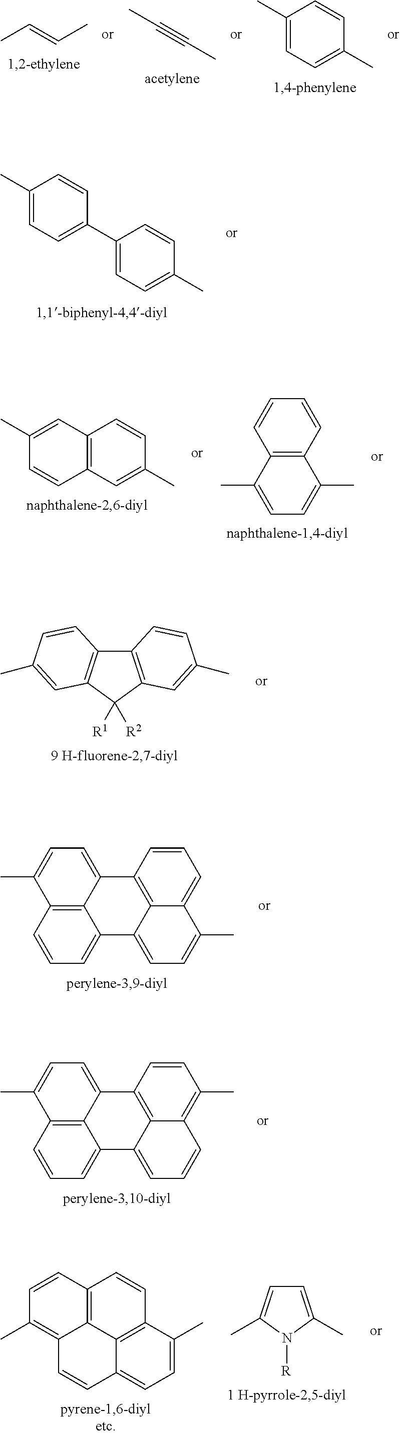

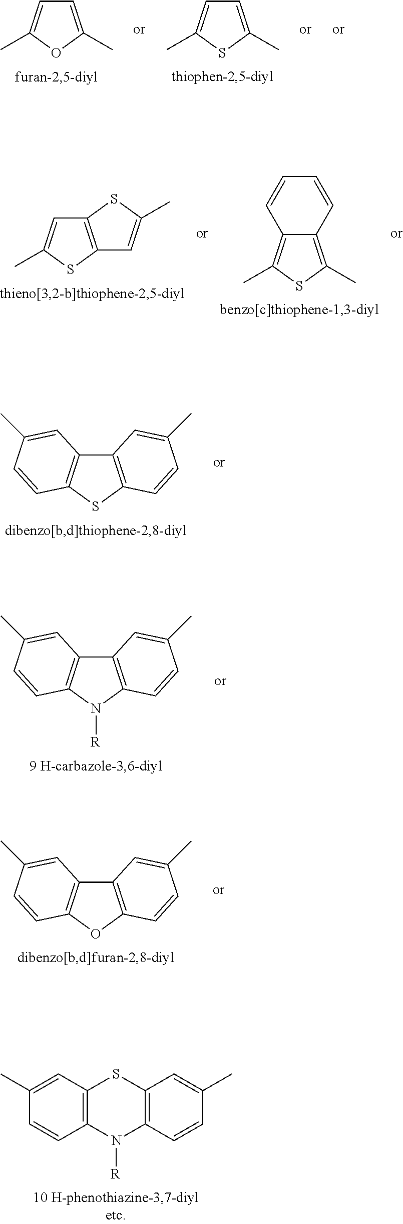

### Formulae V-a and V-b

Some embodiments provide a perylene diester derivative represented by the following general formula (V-a) or general formula (V-b):

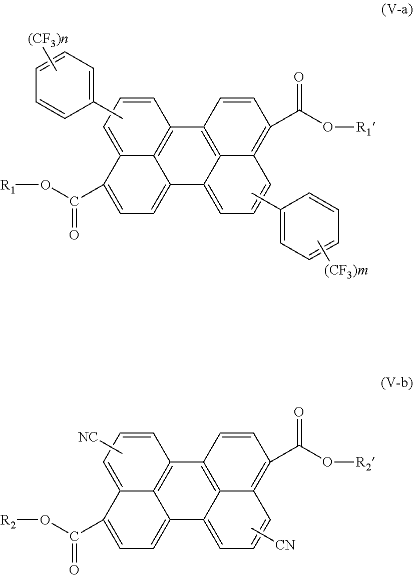

wherein R₁ and R₁′ in formula (V-a) are each independently selected from the group consisting of hydrogen, C₁-C₁₀ alkyl, C₃-C₁₀ cycloalkyl, C₁-C₁₀ alkoxy, C₆-C₁₈ aryl, and C₆-C₂₀ aralkyl; m and n in formula (V-a) are each independently in the range of from 1 to 5; and R₂ and R₂′ in formula (V-b) are each independently selected from the group consisting of a C₆-C₁₈ aryl and C₆-C₂₀ aralkyl. In some embodiments, if one of the cyano groups on formula (V-b) is present on the 4-position of the perylene ring, then the other cyano group is not present on the 10-position of the perylene ring. In some embodiments, if one of the cyano groups on formula (V-b) is present on the 10-position of the perylene ring, then the other cyano group is not present on the 4-position of the perylene ring.

In some embodiments, R₁ and R₁′ are independently selected from the group consisting of hydrogen, C₁-C₆ alkyl, C₂-C₆ alkoxyalkyl, and C₆-C₁₈ aryl. In some embodiments, R₁ and R₁′ are each independently selected from the group consisting of isopropyl, isobutyl, isohexyl, isooctyl, 2-ethyl-hexyl, diphenylmethyl, trityl, and diphenyl. In some embodiments, R₂ and R₂′ are independently selected from the group consisting of diphenylmethyl, trityl, and diphenyl. In some embodiments, each m and n in formula (V-a) is independently in the range of from 1 to 4.

The perylene diester derivative represented by the general formula (V-a) or general formula (V-b) can be made by known methods, such as those described in International Publication No. WO 2012/094409, the contents of which are hereby incorporated by reference in their entirety.

In several embodiments, the wavelength conversion layer comprises more than one chromophore, for example, at least two different chromophores. It may be desirable to have multiple chromophores in the wavelength conversion layer, depending on the solar module that the structure is to be attached. For example, in a solar module system having an optimum photoelectric conversion at about 500 nm wavelength, the efficiency of such a system can be improved by converting photons of other wavelengths into 500 nm wavelengths. In such instance, a first chromophore may act to convert photons having wavelengths in the range of about 400 nm to about 450 nm into photons of a wavelength of about 500 nm, and a second chromophore may act to convert photons having wavelengths in the range of about 450 nm to about 475 nm into photons of a wavelength of about 500 nm. Particular wavelength control may be selected based upon the chromophore(s) utilized.

In several embodiments, two or more chromophores are mixed together within the same layer, such as, for example, in the wavelength conversion layer. In several embodiments, two or more chromophores are located in separate layers or sublayers within the structure. For example, the wavelength conversion layer comprises a first chromophore, and an additional polymer sublayer in between the glass plate and the wavelength conversion layer comprises a second chromophore.

Chromophores can be up-converting or down-converting. In several embodiments, the at least one chromophore may be an up-conversion chromophore, meaning a chromophore that converts photons from lower energy (longer wavelengths) to higher energy (shorter wavelengths). Up-conversion dyes may include rare earth materials which have been found to absorb photons of wavelengths in the infrared (IR) region, ˜975 nm, and re-emit in the visible region (400-700 nm), for example, Yb³⁺, Tm³⁺, Er³⁺, Ho³⁺, and NaYF⁴. Additional up-conversion materials are described in U.S. Pat. Nos. 6,654,161, and 6,139,210, and in the Indian Journal of Pure and Applied Physics, volume 33, pages 169-178, (1995), which are hereby incorporated by reference in their entirety. In several embodiments, the at least one chromophore may be a down-shifting chromophore, meaning a chromophore that converts photons of higher energy (shorter wavelengths) into a lower energy (longer wavelengths). In several embodiments, the down-shifting chromophore may be a derivative of perylene, benzotriazole, or benzothiadiazole, as described above, and in U.S. Provisional Patent Application Nos. 61/430,053, 61/485,093, 61/539,392, and 61/567,534. In several embodiments, the wavelength conversion layer comprises both an up-conversion chromophore and a down-shifting chromophore.

In several embodiments, the wavelength conversion layer of the structure further comprises one or multiple sensitizers. In several embodiments the sensitizer comprises nanoparticles, nanometals, nanowires, or carbon nanotubes. In several embodiments the sensitizer comprises a fullerene. In several embodiments the fullerene is selected from the group consisting of optionally substituted C₆₀, optionally substituted C₇₀, optionally substituted C₈₄, optionally substituted single-wall carbon nanotube, and optionally substituted multi-wall carbon nanotube. In several embodiments, the fullerene is selected from the group consisting of [6,6]-phenyl-C₆₁-butyricacid-methylester, [6,6]-phenyl-C₇₁-butyricacid-methylester, and [6,6]-phenyl-C₈₅-butyricacid-methylester. In several embodiments, the sensitizer is selected from the group consisting of optionally substituted phthalocyanine, optionally substituted perylene, optionally substituted porphyrin, and optionally substituted terrylene. In several embodiments, the wavelength conversion layer of the structure further comprises a combination of sensitizers, wherein the combination of sensitizers is selected from the group consisting of optionally substituted fullerenes, optionally substituted phthalocyanines, optionally substituted perylenes, optionally substituted porphyrins, and optionally substituted terrylenes.

In several embodiments, the wavelength conversion layer of the structure comprises the sensitizer in an amount in the range of about 0.01% to about 5%, by weight based on the total weight of the composition.

In several embodiments, the wavelength conversion layer of the structure further comprises one or multiple plasticizers. In several embodiments, the plasticizer is selected from N-alkyl carbazole derivatives and triphenylamine derivatives.

In several embodiments, of the structure, the glass plate may comprise a composition selected from low iron glass, borosilicate glass, or soda-lime glass. The structure according to any of Claims 1 to 36, wherein the thickness of the glass plate is between about 50 μm and about 5 mm. In several embodiments, of the structure, the composition of the glass plate may also further comprise a strong UV absorber to block harmful high energy radiation into the solar cell.

In several embodiments, of the structure, additional materials or layers may be used such as a glass top sheet, removable liners, edge sealing tape, frame materials, polymer materials, or adhesive layers to adhere additional layers to the system. In several embodiments, the structure further comprises an additional polymer layer containing a UV absorber.

In several embodiments, of the structure, the composition of the wavelength conversion layer further comprises a UV stabilizer, antioxidant, or absorber. In several embodiments, the thickness of the wavelength conversion layer is between about 10 μm and about 2 mm.

In several embodiments, the structure further comprises an adhesive layer. In several embodiments, an adhesive layer adheres the wavelength conversion layer to the glass plate. In several embodiments, an adhesive layer adheres the glass plate to the light incident surface of the solar cell, solar panel, or photovoltaic device. In several embodiments, an adhesive layer is used to adhere additional layers to the structure, such as a removable liner or a polymer film. Various types of adhesives may be used. In several embodiments, the adhesive layer comprises a substance selected from the group consisting of rubber, acrylic, silicone, vinyl alkyl ether, polyester, polyamide, urethane, fluorine, epoxy, ethylene vinyl acetate, and combinations thereof. The adhesive can be permanent or non-permanent. In several embodiments, the thickness of the adhesive layer is between about 1 μm and 100 μm. In several embodiments, the refractive index of the adhesive layer is in the range of about 1.4 to about 1.7.

The structure comprising a wavelength conversion layer on a glass plate may also comprise additional layers. For example, additional polymer films, or adhesive layers may be included. In several embodiments, the structure further comprises an additional polymer layer containing a UV absorber, which may act to block high energy irradiation and prevent photo-degradation of the chromophore compound. Other layers may also be included to further enhance the photoelectric conversion efficiency of solar modules. For example, the structure may additionally have a microstructured layer, which is designed to further enhance the solar harvesting efficiency of solar modules by decreasing the loss of photons to the environment which are often re-emitted from the chromophore after absorption and wavelength conversion in a direction that is away from the photoelectric conversion layer of the solar module device (see U.S. Provisional Patent Application No. 61/555,799, which is hereby incorporated by reference). A layer with various microstructures on the surface (i.e. pyramids or cones) may increase internal reflection and refraction of the photons into the photoelectric conversion layer of the device, further enhancing the solar harvesting efficiency of the device. Additional layers may also be incorporated into the pressure sensitive adhesive type of wavelength conversion tape.

The structure comprising a wavelength conversion layer on a glass plate may further comprise one or more removable liners, wherein the removable liner(s) may be adhered onto the wavelength conversion layer and/or adhered onto the glass plate and is appropriately removed when the structure is installed onto a solar cell, solar panel, or photovoltaic device. In several embodiments, the removable liner(s) may be designed to protect the wavelength conversion layer. In several embodiments, the removable liner(s) may be designed to prevent photon penetration into the structure, such that photodegradation of the wavelength conversion layer is not possible until the liner is removed. The removable liner used in the invention can be appropriately selected, without any especial limitation, from members which have been hitherto used as a removable liner. Specific examples of the removable liner include plastic films such as polyethylene, polypropylene, polyethylene terephthalate, and polyester films; paper products such as glassine paper, coated paper, and laminated paper products; porous material sheets such as cloth and nonwoven fabric sheets; and various thin bodies, such as a net, a foamed sheet, a metal foil, and laminates thereof. Any one of the plastic films is preferably used since it is excellent in surface flatness or smoothness. The film is not limited to any especial kind if the film can protect the structure. In several embodiments, the removable liner consists of a material selected from fluoropolymers, polyethylene terephthalate, polyethylene, polypropylene, polyester, polybutene, polybutadiene, polymethylpentene, polyvinyl chloride, vinyl chloride copolymer, polybutalene terepthalate, polyurethane, ethylene-vinyl acetate, glassine paper, coated paper, laminated paper, cloth, nonwoven fabric sheets, or metal foil. In several embodiments, the thickness of the removable liner is between about 10 μm and about 100 μm.

In several embodiments the structure comprising a wavelength conversion layer on a glass plate, wherein the wavelength conversion layer comprises at least one chromophore and an optically transparent polymer matrix, is formed by first synthesizing the chromophore/polymer solution in the form of a liquid or gel, applying the chromophore/polymer solution to a glass plate using standard methods of application, such as spin coating or drop casting, then curing the chromophore/polymer solution to a solid form (i.e. heat treating, UV exposure, etc.) as is determined by the formulation design.

In another embodiment the structure comprising a wavelength conversion layer on a glass plate, wherein the wavelength conversion layer comprises at least one chromophore and an optically transparent polymer matrix, is formed by first synthesizing a chromophore/polymer thin film, and then adhering the chromophore/polymer thin film to the glass plate using an optically transparent and photostable adhesive and/or laminator.

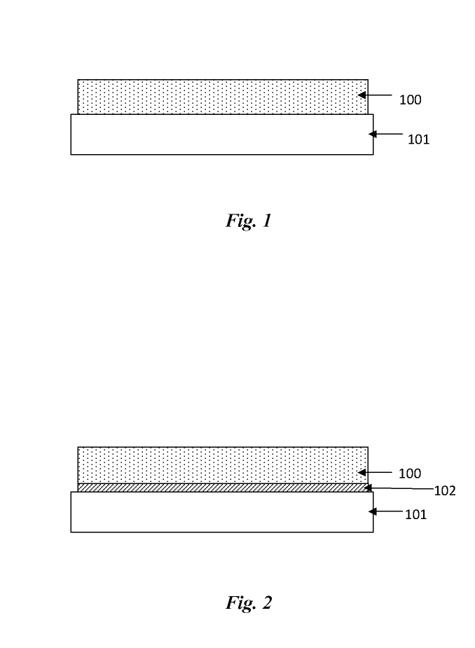

In some embodiments as shown in FIG. 1, the structure comprises a wavelength conversion layer 100 on a glass plate 101, wherein the wavelength conversion layer comprises a transparent polymer matrix and at least one chromophore.

In some embodiments as shown in FIG. 2, the structure comprising a wavelength conversion layer 100 on a glass plate 101, further comprises an adhesive layer 102 in between the wavelength conversion layer and the glass plate, wherein the wavelength conversion layer comprises a polymer matrix and at least one chromophore.

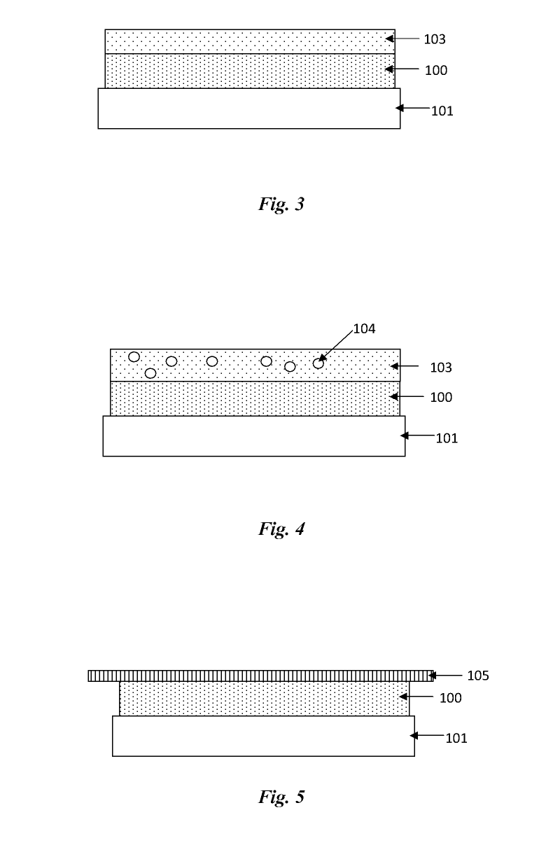

In some embodiments as shown in FIG. 3, the structure comprising a wavelength conversion layer 100 on a glass plate 101, further comprises a protective polymer layer 103 designed to prevent oxygen and moisture penetration into the wavelength conversion layer, wherein the wavelength conversion layer comprises a polymer matrix and at least one chromophore.

In some embodiments as shown in FIG. 4, the structure comprising a wavelength conversion layer 100 on a glass plate 101, further comprises a protective polymer layer 103 which contains a UV absorber 104 that prevents high energy photons from contacting the wavelength conversion layer, wherein the wavelength conversion layer comprises a polymer matrix and at least one chromophore.

In some embodiments as shown in FIG. 5, the structure comprising a wavelength conversion layer 100 on a glass plate 101, further comprises a removable liner 105 on top of the wavelength conversion layer to protect it from photo-degradation. The removable liner may be removed just prior to, or after, the structure is installed onto a solar cell, solar panel, or photovoltaic device, to allow photons to pass through to the device.

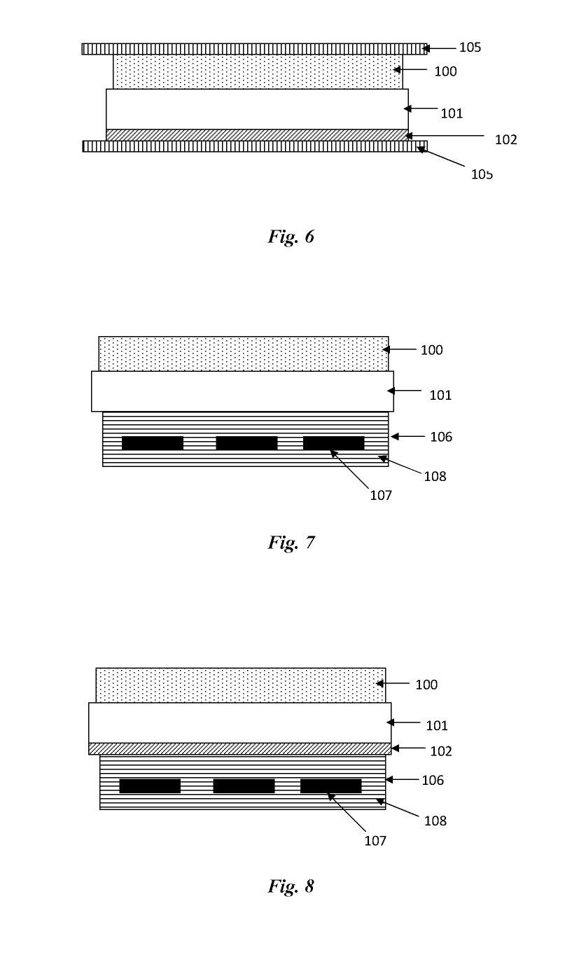

In some embodiments as shown in FIG. 6, the structure comprising a wavelength conversion layer 100 on a glass plate 101, further comprises a removable liner 105 on top of the wavelength conversion layer and underneath the glass plate to protect it from photo-degradation. The removable liners may be removed just prior to, or after, the structure is installed onto a solar cell, solar panel, or photovoltaic device, to allow photons to pass through to the device.

In another aspect of the invention, a method of improving the performance of a solar cell, a solar panel, or photovoltaic device comprises applying the structure comprising a wavelength conversion layer on a glass plate, disclosed herein, to a solar cell, solar panel, or photovoltaic device. In several embodiments of the method, the structure is applied to the solar cell, solar panel, or photovoltaic device, using a laminator. In several embodiments, the structure is applied to the solar cell, solar panel, or photovoltaic device, using a transparent photostable adhesive. Devices, such as a Silicon based device, a III-V or II-VI PN junction device, a Copper-Indium-Gallium-Selenium (CIGS) thin film device, an organic sensitizer device, an organic thin film device, or a Cadmium Sulfide/Cadmium Telluride (CdS/CdTe) thin film device, can be improved. In several embodiments of the method, the solar panel contains at least one photovoltaic device or solar cell comprising a Cadmium Sulfide/Cadmium Telluride solar cell. In several embodiments, the photovoltaic device or solar cell comprises a Copper Indium Gallium Diselenide solar cell. In several embodiments, the photovoltaic or solar cell comprises a III-V or II-VI PN junction device. In several embodiments, the photovoltaic or solar cell comprises an organic sensitizer device. In several embodiments, the photovoltaic or solar cell comprises an organic thin film device. In several embodiments, the photovoltaic device or solar cell comprises an amorphous Silicon (a-Si) solar cell. In several embodiments, the photovoltaic device or solar cell comprises a microcrystalline Silicon (μc-Si) solar cell. In several embodiments, the photovoltaic device or solar cell comprises a crystalline Silicon (c-Si) solar cell.

In some embodiments as shown in FIG. 7 and FIG. 8, the structure comprising a wavelength conversion layer 100 on a glass plate 101, is applied to a solar panel 106 comprising multiple solar cells 107 arranged in an encapsulation material 108. The structure enhances solar harvesting efficiency of the solar panel.

The object of this current invention is to provide a structure comprising a wavelength conversion layer on a glass plate which may be suitable for application to solar cells, photovoltaic devices, solar modules, and solar panels. By using this structure, we can expect improved light conversion efficiency.

Synthetic methods for forming the structure comprising a wavelength conversion layer on a glass plate are not restricted, but may follow the example synthetic procedures described as Scheme 1 and Scheme 2 detailed below.

### Scheme 1: Wet Processing General Procedure for Forming the WLC Layer

In several embodiments, a wavelength conversion layer 100, which comprises at least one chromophore, and an optically transparent polymer matrix, is fabricated onto a glass plate. The wavelength conversion layer is fabricated by (i) preparing a polymer solution with dissolved polymer powder in a solvent such as tetrachloroethylene (TCE), cyclopentanone, dioxane, etc., at a predetermined ratio; (ii) preparing a chromophore solution containing a polymer mixture by mixing the polymer solution with the chromophore at a predetermined weight ratio to obtain a chromophore-containing polymer solution, (iii) forming the chromophore/polymer film by directly casting the chromophore-containing polymer solution onto a glass plate, then heat treating the substrate from room temperature up to 100° C. in 2 hours, completely removing the remaining solvent by further vacuum heating at 130° C. overnight, and, (iv) the layer thickness can be controlled from 0.1 μm˜1 mm by varying the chromophore/polymer solution concentration and evaporation speed.

### Scheme 2: Dry Processing General Procedure for Forming the WLC Material

In several embodiments, a wavelength conversion layer 100, which comprises at least one chromophore, and an optically transparent polymer matrix, is fabricated onto a glass plate. The wavelength conversion layer is fabricated by (i) mixing polymer powders or pellets and chromophore powders together at a predetermined ratio by a mixer at a certain temperature; (ii) degassing the mixture between 1-8 hours at a certain temperature; (iii) then forming the layer using an extruder; (v) the extruder controls the layer thickness from 1 μm˜1 mm.

Once the wavelength conversion layer is formed it can be adhered to the glass plate using an optically transparent and photostable adhesive.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed examples which follow.

### EXAMPLES

The embodiments will be explained with respect to preferred embodiments which are not intended to limit the present invention. In the present disclosure, the listed substituent groups include both further substituted and unsubstituted groups unless specified otherwise. Further, in the present disclosure where conditions and/or structures are not specified, the skilled artisan in the art can readily provide such conditions and/or structures, in view of the present disclosure, as a matter of routine experimentation.

### a) Synthesis of Chromophore Compounds

The down-shifting chromophore compounds may be synthesized according to the methods described in U.S. Provisional Patent Application Nos. 61/430,053, 61/485,093, 61/539,392, and 61/567,534.

### b) Wet Process Synthesis of WLC on Glass Plate

In several embodiments, a wavelength conversion layer 100, which comprises at least one chromophore, and an optically transparent polymer matrix, is fabricated onto a glass plate. The wavelength conversion layer is fabricated by (i) preparing a 20 wt % Polyvinyl butyral (PVB) (Aldrich and used as received) polymer solution with dissolved polymer powder in cyclopentanone; (ii) preparing a chromophore containing a PVB matrix by mixing the PVB polymer solution with the synthesized chromophore at a weight ratio (Chromophore/PVB) of 0.3 wt % to obtain a chromophore-containing polymer solution; (iii) forming the chromophore/polymer film by directly casting the chromophore-containing polymer solution onto a glass substrate, then heat treating the substrate from room temperature up to 100° C. in 2 hours, completely removing the remaining solvent by further vacuum heating at 130° C. overnight, and (iv) peeling off the chromophore/polymer film under the water and then drying out the free-standing polymer film before use. After the film is dried out, it is hot pressed into a wavelength conversion layer of ˜250 μm thickness.

### c) Application of Structure to Solar Cell

Then, in several embodiments, the structure comprising a wavelength conversion film on a glass plate is laminated onto a commercial crystalline Silicon solar cell, using a laminator in vacuum at 130° C. with the wavelength conversion layer as the front surface, similar to the structure shown in FIG. 7.

### d) Measurement of the Efficiency Enhancement

The solar cell photoelectric conversion efficiency was measured by a Newport 400W full spectrum solar simulator system. The light intensity was adjusted to one sun (AM1.5G) by a 2 cm×2 cm calibrated reference monocrystalline silicon solar cell. Then the I-V characterization of the crystalline Silicon solar cell was performed under the same irradiation and its efficiency is calculated by the Newport software program which is installed in the simulator. After determining the stand alone efficiency of the cell, the efficiency enhancement of the cell with the structure comprising a wavelength conversion layer on a glass plate is measured. The structure was cut to the same shape and size of the light incident active window of the crystalline silicon solar cell, and applied to the light incident front glass substrate of the crystalline silicon solar cell using the method described above.

The efficiency enhancement of the solar cell with the attached film was determined using the following equation:

Efficiency Enhancement=(η_{cell+film}−η_{cell})η_{cell}*100%

The efficiency enhancement with the applied structures depend on the chromophore used in the wavelength conversion film. In some embodiments, the efficiency enhancement of the crystalline silicon solar cell with the application of the structure comprising a wavelength conversion film on a glass plate is greater than 2%. In some embodiments, the efficiency enhancement is greater than 4%. In some embodiments, the efficiency enhancement is greater than 5%.

### Example 2

Example 2 followed the same procedure as given in Example 1 steps a-d, except that a dry processing technique was used to fabricate the wavelength conversion layer as defined below.

### b) Dry Process Synthesis of a WLC on Glass Plate

In several embodiments, a wavelength conversion layer 100, which comprises at least one chromophore, and an optically transparent polymer matrix, is fabricated onto a glass plate using a dry processing technique.

The wavelength conversion layer is fabricated by (i) mixing PVB powders with the chromophore at a predetermined ratio of 0.3% by weight in a mixer at 170° C.; (ii) degassing the mixture between 1-8 hours at 150° C.; (iii) then forming the layer using an extruder or hot press at 120° C.; (iv) the layer thickness was 250 μm which was controlled by the extruder. Once the wavelength conversion layer is formed it is then laminated onto a ˜3 mm thick glass plate using a laminator.

The efficiency enhancement of the Example 2 structures also depend on the chromophore used in the wavelength conversion film. In some embodiments, the efficiency enhancement of the crystalline silicon solar cell with the application of the structure comprising a wavelength conversion film on a glass plate is greater than 2%. In some embodiments, the efficiency enhancement is greater than 4%. In some embodiments, the efficiency enhancement is greater than 5%.

The object of this current invention is to provide a structure comprising a wavelength conversion layer on a glass plate which may be suitable for direct application to the light incident surface of solar cells, photovoltaic devices, solar modules, and solar panels. As illustrated by the above examples, the use of this structure improves the solar cell light conversion efficiency.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

It will be understood by those of skill in the art that numerous and various modifications can be made without departing from the spirit of the present invention. Therefore, it should be clearly understood that the forms of the present invention are illustrative only and are not intended to limit the scope of the present invention.

1. A wavelength converting device comprising:
a glass plate; and
a first wavelength conversion layer over the glass plate, wherein the wavelength conversion layer comprises at least one chromophore and an polymer matrix.

2. The wavelength converting device according to claim 1, wherein the polymer matrix is optically transparent.

3. The wavelength converting device according to claim 1, wherein the polymer matrix is formed from a substance selected from the group consisting of polyethylene terephthalate, polymethyl methacrylate, polyvinyl butyral, ethylene vinyl acetate, ethylene tetrafluoroethylene, polyimide, amorphous polycarbonate, polystyrene, siloxane sol-gel, polyurethane, polyacrylate, and combinations thereof.

4. The wavelength converting device according to claim 1, wherein the polymer matrix comprises at least one polymer selected from the group consisting of a host polymer, a copolymer, a host polymer and a co-polymer, multiple polymers, multiple polymers and copolymers, and multiple copolymers.

5. The wavelength converting device according to claim 1, wherein the polymer matrix has a refractive index between about 1.4 to about 1.7.

6. The wavelength converting device according to claim 1, wherein the at least one chromophore is present in the polymer matrix of the first wavelength conversion layer in an amount of between about 0.01 wt % to about 3 wt %.

7. The wavelength converting device according to claim 1, wherein the at least one chromophore is present in the polymer matrix of the first wavelength conversion layer in an amount of between about 0.05 wt % to about 2 wt %.

8. The wavelength converting device according to claim 1, wherein the at least one chromophore is present in the polymer matrix of the first wavelength conversion layer in an amount of between about 0.1 wt % and about 1 wt %.

9. The wavelength converting device according to claim 1, wherein the first wavelength conversion layer comprises two or more chromophores.

10. The wavelength converting device according to claim 1, wherein the at least one chromophore is an up-conversion chromophore.

11. The wavelength converting device according to claim 1, wherein the at least one chromophore is a down-shifting chromophore.

12. The wavelength converting device according to claim 1, further comprises a second wavelength conversion layer.

13. The wavelength converting device according to claim 12, wherein the second wavelength conversion layer comprises at least one chromophore that is the same or different from the at least one chromophore in the first wavelength conversion layer.

14. The wavelength converting device according to claim 1, wherein the at least one chromophore in the first wavelength conversion layer is an organic dye.

15. The wavelength converting device according to claim 1, wherein the at least one chromophore in the first wavelength conversion layer is selected from the group consisting of perylene dyes, benzotriazole dyes, and benzothiadiazole dyes.

16. The wavelength converting device according to claim 1, wherein the at least one chromophore in the first wavelength conversion layer is represented by formula (I-a) or (I-b): 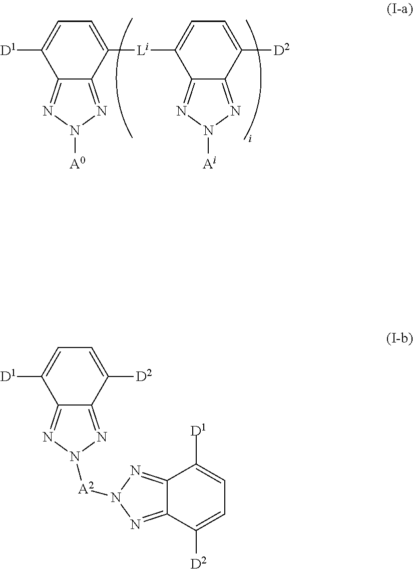
wherein:
i is an integer in the range of 0 to 100;
A⁰ and Aⁱ are each independently selected from the group consisting of optionally substituted alkyl, optionally substituted alkyenyl, optionally substituted heteroalkyl, optionally substituted aryl, optionally substituted heteroaryl, optionally substituted amino, optionally substituted amido, optionally substituted cyclo amido, optionally substituted cyclo imido, optionally substituted alkoxy, and optionally substituted carboxy, and optionally substituted carbonyl;
A² is selected from the group consisting of optionally substituted alkylene, optionally substituted alkenylene, optionally substituted arylene, optionally substituted heteroarylene, ketone, ester, and 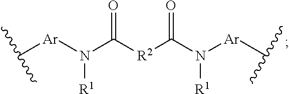
wherein Ar is optionally substituted aryl or optionally substituted heteroaryl; le is selected from the group consisting of H, alkyl, alkenyl, aryl, heteroaryl, aralkyl, alkaryl; and R² is selected from the group consisting of optionally substituted alkylene, optionally substituted alkenylene, optionally substituted arylene, optionally substituted heteroarylene, ketone, and ester; or R¹ and R² may be connected together to form a ring.
D¹ and D² are independently selected from the group consisting of hydrogen, optionally substituted alkoxy, optionally substituted aryloxy, optionally substituted acyloxy, optionally substituted alkyl, optionally substituted aryl, optionally substituted heteroaryl, optionally substituted amino, amido, cyclo amido, and cyclo imido, provided that D¹ and D² are not both hydrogen; and
Lⁱ is independently selected from the group consisting of optionally substituted alkylene, optionally substituted alkenylene, optionally substituted alkynylene, optionally substituted arylene, and optionally substituted heteroarylene.

17. The wavelength converting device according to claim 1, wherein the at least one chromophore in the first wavelength conversion layer is represented by formula (II-a) or (II-b): 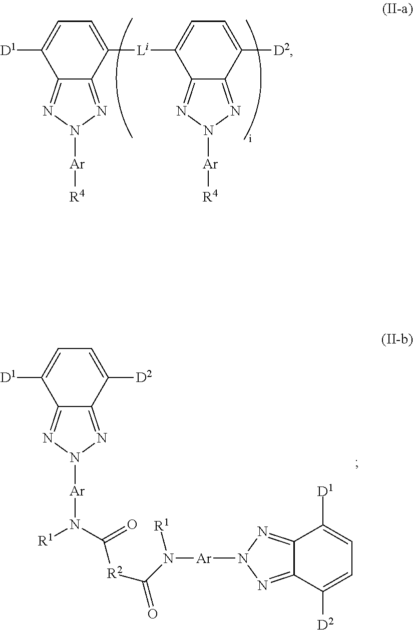
wherein:
i is an integer in the range of 0 to 100;
Ar is optionally substituted aryl or optionally substituted heteroaryl;
R⁴ is 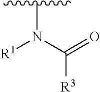
or optionally substituted cyclic imido;
R¹ is each independently selected from the group consisting of H, alkyl, alkenyl, aryl, heteroaryl, aralkyl, and alkaryl;
R³ is each independently selected from the group consisting of optionally substituted alkyl, optionally substituted alkenyl, optionally substituted aryl, and optionally substituted heteroaryl; or R¹ and R³ may be connected together to form a ring;
R² is selected from the group consisting of optionally substituted alkylene, optionally substituted alkenylene, optionally substituted arylene, optionally substituted heteroarylene;
D¹ and D² are each independently selected from the group consisting of hydrogen, optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido, provided that D¹ and D² are not both hydrogen; and
L¹ is independently selected from the group consisting of optionally substituted alkylene, optionally substituted alkenylene, optionally substituted alkynylene, optionally substituted arylene, optionally substituted heteroarylene.

18. The wavelength converting device according to claim 1, wherein the at least one chromophore in the first wavelength conversion layer is represented by formula (III-a) or (III-b): 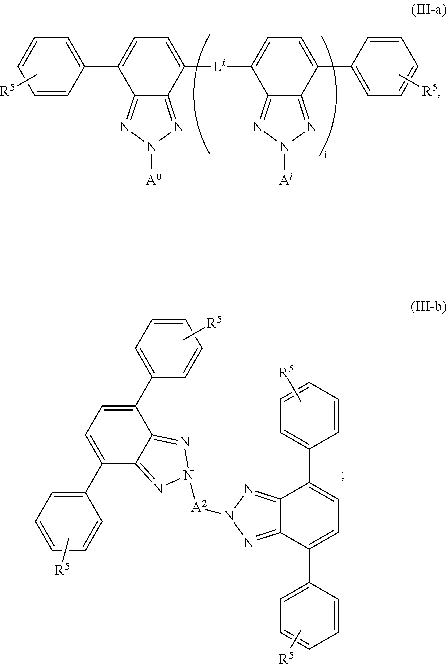
wherein:
i is an integer in the range of 0 to 100.
A⁰ and A′ are each independently selected from the group consisting of optionally substituted alkyl, optionally substituted alkenyl, optionally substituted heteroalkyl, optionally substituted amido, optionally substituted alkoxy, optionally substituted cabonyl, and optionally substituted carboxy;
each R⁵ is independently selected from the group consisting of optionally substituted alkoxy, optionally substituted aryloxy, optionally substituted acyloxy, and amino;
A² is selected from the group consisting of optionally substituted alkylene, optionally substituted alkenylene, optionally substituted arylene, optionally substituted heteroarylene, ketone, ester, and 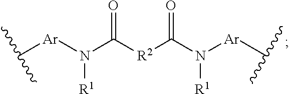
wherein Ar is optionally substituted aryl or optionally substituted heteroaryl; le is selected from the group consisting of H, alkyl, alkenyl, aryl, heteroaryl, aralkyl, alkaryl; and R² is selected from the group consisting of optionally substituted alkylene, optionally substituted alkenylene, optionally substituted arylene, optionally substituted heteroarylene, ketone, and ester; or R¹ and R² may be connected together to form a ring; and
L¹ is independently selected from the group consisting of optionally substituted alkylene, optionally substituted alkenylene, optionally substituted alkynylene, optionally substituted arylene, optionally substituted heteroarylene.

19. The wavelength converting device according to claim 1, wherein the at least one chromophore in the first wavelength conversion layer is represented by formula (IV): 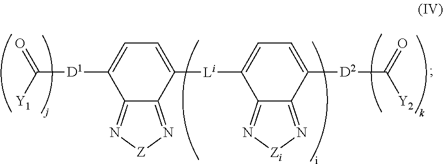
wherein,
i is an integer in the range of 0 to 100;
Z and Zᵢ are each independently selected from the group consisting of —O—, —S—, —Se—, —Te—, —NR⁶—, —CR⁶═CR⁶—, and —CR⁶═N—, wherein R⁶ is hydrogen, optionally substitute C₁-C₆ alkyl, or optionally substituted C₁-C₁₀ aryl; and
D¹ and D² are independently selected from the group consisting of optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido;
j is 0, 1 or 2, and k is 0, 1, or 2;
Y₁ and Y₂ are independently selected from the group consisting of optionally substituted aryl, optionally substituted alkyl, optionally substituted cycloalkyl, optionally substituted alkoxy, and optionally substituted amino; and
L¹ is independently selected from the group consisting of optionally substituted alkylene, optionally substituted alkenylene, optionally substituted alkynylene, optionally substituted arylene, optionally substituted heteroarylene.

20. The wavelength converting device according to claim 1, wherein the at least one chromophore in the first wavelength conversion layer is a perylene diester derivative represented by the following formula (V-a) or formula (V-b): 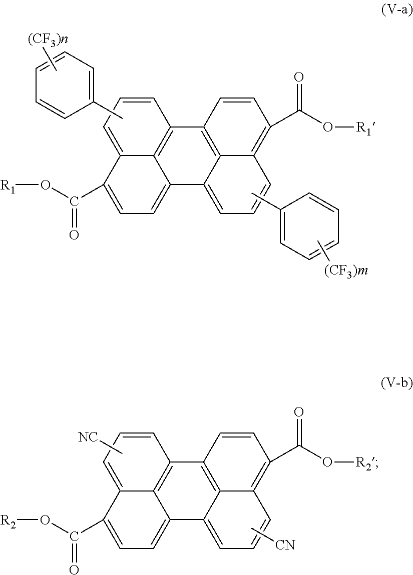
wherein R₁ and R₁′ in formula (V-a) are each independently selected from the group consisting of hydrogen, C₁-C₁₀ alkyl, C₃-C₁₀ cycloalkyl, C₁-C₁₀ alkoxy, C₆-C₁₈ aryl, and C₆-C₂₀ aralkyl; m and n in formula (V-a) are each independently in the range of from 1 to 5; and R₂ and R₂′ in formula (V-b) are each independently selected from the group consisting of a C₆-C₁₈ aryl and C₆-C₂₀ aralkyl.

21. The wavelength converting device of claim 1, wherein the first wavelength conversion layer further comprises one or more sensitizers.

22. The wavelength converting device of claim 21, wherein the one or more sensitizers is selected from the group comprising of nanoparticles, nanometals, nanowires, carbon nanotubes, fullerenes, optionally substituted fullerenes, optionally substituted phthalocyanines, optionally substituted perylenes, optionally substituted porphyrins, optionally substituted terrylenes, and a combination thereof.

23. The wavelength converting device of claim 22, wherein the one or more sensitizers is fullerene selected from the group consisting of optionally substituted C₆₀, optionally substituted C₇₀, optionally substituted C₈₄, optionally substituted single-wall carbon nanotube, and optionally substituted multi-wall carbon nanotube.

24. The wavelength converting device of claim 23, wherein the one or more sensitizers is fullerene is selected from the group consisting of [6,6]-phenyl-C₆₁-butyricacid-methylester, [6,6]-phenyl-C₇₁-butyricacid-methylester, and [6,6]-phenyl-C₈₅-butyricacid-methylester.

25. The wavelength converting device of claim 21, wherein the composition comprises the sensitizer in an amount in the range of about 0.01% to about 5%, by weight based upon the total weight of the composition.

26. The wavelength converting device of claim 1, wherein the first wavelength conversion layer further comprises one or more plasticizers.

27. The wavelength converting device of claim 26, wherein the plasticizer is selected from group consisting of N-alkyl carbazole derivatives and triphenylamine derivatives.

28. The wavelength converting device according to claim 1, wherein the first wavelength conversion layer further comprises a UV stabilizer, antioxidant, or UV absorber.

29. The wavelength converting device according to claim 1, further comprises one or more additional layers each selected from the group consisting of glass sheet, removable liner, edge sealing tape, frame material, polymer material, and adhesive layer.

30. The wavelength converting device according to claim 1, further comprising an adhesive layer between the glass plate and the first wavelength conversion layer.

31. The wavelength converting device according to claim 30, wherein the adhesive layer comprises acrylic, ethylene vinyl acetate, or polyurethane.

32. The wavelength converting device according to claim 30, wherein the thickness of the adhesive layer is between about 1 μm and about 100 μm.

33. The wavelength converting device according to claim 30, wherein the refractive index of the adhesive layer is in the range of about 1.4 to about 1.7.

34. The wavelength converting device according to claim 33, wherein the refractive index of the adhesive layer is in the range of about 1.45 to about 1.55.

35. The wavelength converting device according to claim 1, wherein the wavelength converting device further comprises an additional polymer layer comprising a UV absorber.

36. The wavelength converting device according to claim 1, wherein the thickness of the first wavelength conversion layer is between about 10 μm and about 2 mm.

37. The wavelength converting device according to claim 1, wherein the glass plate comprises a material selected from low iron glass, borosilicate glass, or soda-lime glass.

38. The wavelength converting device according to claim 1, wherein the glass plate further comprises a UV absorber.

39. The wavelength converting device according to of 1 to 38, wherein the thickness of the glass plate is between about 50 μm and about 5 mm.

40. The wavelength converting device according to claim 1, further comprising at least one removable liner.

41. The wavelength converting device according to claim 40, wherein the removable liner is attached to the first wavelength conversion layer, the glass plate, or both.

42. The wavelength converting device according to claim 40, wherein the removable liner comprises a plastic film.

43. The wavelength converting device according to claim 40, wherein the removable liner is selected from the group consisting of: fluoropolymer, polyethylene terephthalate, polyethylene, polypropylene, polyester, polybutene, polybutadiene, polymethylpentene, polyvinyl chloride, vinyl chloride copolymer, polybutalene terepthlalate, polyurethane, ethylene-vinyl acetate, glassine paper, coated paper, laminated paper, cloth, nonwoven fabric sheets, and metal foil.

44. The wavelength converting device according to claim 40, wherein the thickness of the removable liner is between about 10 μm and about 100 μm.

45. A method of forming the wavelength converting device of claim 1, comprising the steps of:
formulating a solution comprising a polymer material and at least one chromophore dissolved in a solvent;
spin coating the solution directly onto the glass plate to obtain a wavelength conversion layer; and
removing the solvent from the wavelength conversion layer by drying the wavelength converting device in an oven.

46. A method of forming the wavelength converting device of claim 1, comprising the steps of:
mixing a powdered polymer material and one or more chromophores to form a mixture;
heating the mixture using an extruder to form a wavelength conversion layer; and
applying the wavelength conversion layer to a glass plate directly using a laminator.

47. A method of improving the performance of a solar cell, a solar panel, or photovoltaic device comprising:
applying the wavelength converting device of claim 1 directly onto a light incident surface of the solar cell, solar panel, or photovoltaic device.

48. The method according to claim 47, wherein the solar panel or solar cell contains at least one device selected from the group consisting of a Silicon based device, a III-V or II-VI PN junction device, a Copper-Indium-Gallium-Selenium (CIGS) thin film device, an organic sensitizer device, an organic thin film device, and a Cadmium Sulfide/Cadmium Telluride (CdS/CdTe) thin film device.

49. The method according to claim 47, wherein the light incident surface of the solar cell, solar panel, or photovoltaic device comprises glass or polymer.

50. The method according to claim 47, wherein wavelength converting device is applied to the light incident surface using an adhesive layer.
